(19) United States
(12) Patent Application Publication
(10) Pub. No.: US 2013/0075818 A1
(43) Pub. Date: Mar. 28, 2013

(54) 3D Semiconductor Device and Method of Manufacturing Same

(71) Applicants: Tsung-Lin Lee, Hsinchu City (TW); Feng Yuan, Yonghe City (TW); Chih Chieh Yeh, Taipei City (TW); Clement Hsingjen Wann, Carmel, NY (US)

(72) Inventors: Tsung-Lin Lee, Hsinchu City (TW); Feng Yuan, Yonghe City (TW); Chih Chieh Yeh, Taipei City (TW); Clement Hsingjen Wann, Carmel, NY (US)

(73) Assignee: TAIWAN SEMICONDUCTOR MANUFACTURING COMPANY, LTD., Hsinchu (TW)

(21) Appl. No.: 13/243,723

(22) Filed: Sep. 23, 2011

(51) Int. Cl. H01L 27/12; H01L 21/336

(52) U.S. Cl. 257/347; 438/158; 257/E27.112; 257/E21.409

(57) ABSTRACT

A semiconductor device and method for fabricating a semiconductor device is disclosed. An exemplary semiconductor device includes a substrate and a 3D structure disposed over the substrate. The semiconductor device further includes a dielectric layer disposed over the 3D structure, a WFMG layer disposed over the dielectric layer, and a gate structure disposed over the WFMG layer. The gate structure traverses the 3D structure and separates a source region and a drain region of the 3D structure. The source and drain region define a channel region therebetween. The gate structure induces a stress in the channel region.

### BACKGROUND

The semiconductor integrated circuit (IC) industry has experienced rapid growth. In the course of the IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC manufacturing are needed.

For example, as the semiconductor industry has progressed into nanometer technology process nodes in pursuit of higher device density, higher performance, and lower costs, challenges from both fabrication and design have resulted in the development of three dimensional (3D) designs. Although existing 3D devices and methods of fabricating 3D devices have been generally adequate for their intended purposes, as device scaling down continues, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flowchart illustrating a method of forming a semiconductor device according to various aspects of the present disclosure.

FIGS. 2-6 illustrate diagrammatic cross-sectional side views of one embodiment of a semiconductor device at various stages of fabrication, according to the method of FIG. 1.

FIG. 7 illustrates a perspective view of one embodiment of a semiconductor device, according to the method of FIG. 1.

FIG. 8 illustrates a partial perspective view of one embodiment of a semiconductor device and the direction of stress forces, according to the method of FIG. 1.

FIGS. 9-10 illustrate diagrammatic cross-sectional side views of one embodiment of a semiconductor device at various stages of fabrication, according to the method of FIG. 1.

FIG. 11 illustrates a partial perspective view one embodiment of a semiconductor device and the direction of stress forces, according to the method of FIG. 1.

FIG. 12 illustrates a diagrammatic cross-sectional side view of one embodiment of a semiconductor device at one stage of fabrication, according to the method of FIG. 1.

FIG. 13 is a flowchart illustrating a method of forming a semiconductor device according to various aspects of the present disclosure.

FIGS. 14-20 illustrate diagrammatic cross-sectional side views of one embodiment of a semiconductor device at various stages of fabrication, according to the method of FIG. 13.

FIG. 21 is a flow chart of a method for fabricating an integrated circuit device according to various aspects of the present disclosure.

FIGS. 22-28 illustrate diagrammatic cross-sectional side views of one embodiment of a semiconductor device at various stages of fabrication, according to the method of FIG. 21.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. It is understood that those skilled in the art will be able to devise various equivalents that, although not explicitly described herein, embody the principles of the present invention.

Examples of devices that can benefit from one or more embodiments of the present invention are three dimensional (3D) semiconductor devices. Such a device, for example, is a fin-like field effect transistor (FinFET). The FinFET device, for example, may be a P-type metal-oxide-semiconductor (PMOS) FinFET device or a N-type metal-oxide-semiconductor (NMOS) FinFET device. The following disclosure will continue with a FinFET example to illustrate various embodiments of the present invention. It is understood, however, that the invention should not be limited to a particular type of device, except as specifically claimed.

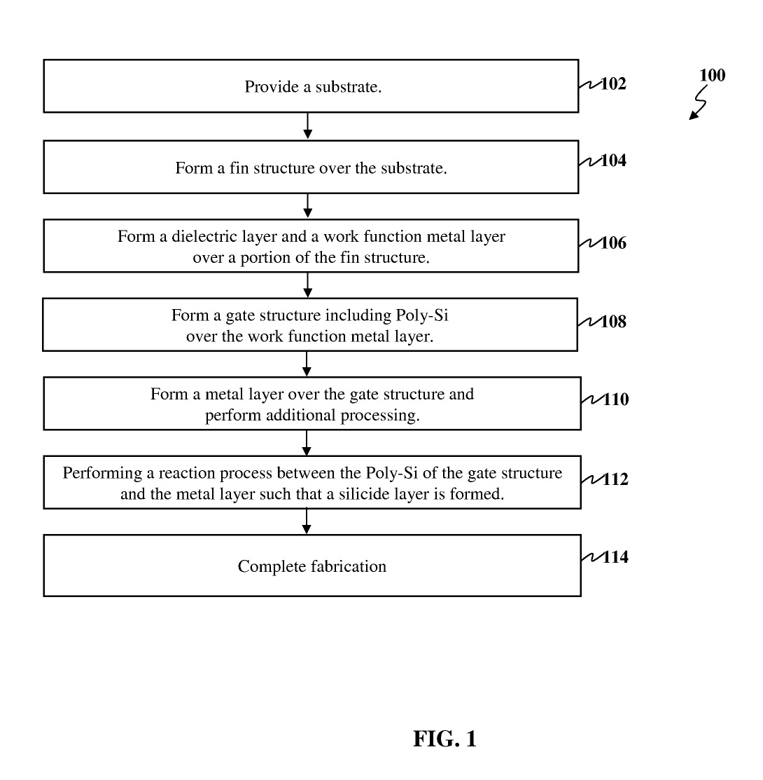

FIG. 1 is a flow chart of a method 100 for fabricating an integrated circuit device according to various aspects of the present disclosure. In the present embodiment, the method 100 is for fabricating an integrated circuit device that includes a PMOS FinFET device. The method 100 begins at block 102 where a semiconductor substrate is provided. At blocks 104 and 106, a fin structure (which is 3D) is formed over the substrate, and a dielectric layer and a work function metal layer are formed over a portion of the fin structure. At block 108, a gate structure is formed over the work function metal layer. The gate structure traverses the fin structure, separating a source region and a drain region of the fin structure. A channel region is defined between the source and drain regions. The method continues with block 110 where a metal layer is formed over the gate structure and additional processing is performed. At block 112, a reaction process is performed between the Poly-Si of the gate structure and the metal layer such that silicide is formed. The method 100 continues with block 114 where fabrication of the integrated circuit device is completed. Additional steps can be provided before, during, and after the method 100, and some of the steps described can be replaced or eliminated for other embodiments of the method. The discussion that follows illustrates various embodiments of an integrated circuit device that can be fabricated according to the method 100 of FIG. 1.

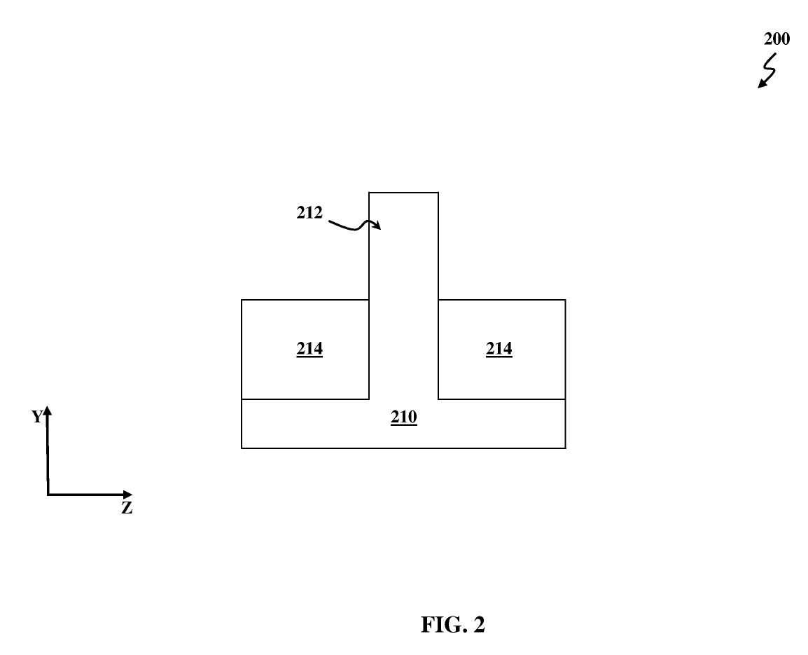

FIGS. 2 to 6 illustrate diagrammatic cross-sectional side views of one embodiment of a semiconductor device, in portion or entirety, at various stages of fabrication according to the method 100 of FIG. 1. In the present disclosure, the term FinFET device refers to any fin-based, multi-gate transistor. The FinFET device 200 may be included in a microprocessor, memory cell, and/or other integrated circuit device. FIGS. 2-6 have been simplified for the sake of clarity to better understand the inventive concepts of the present disclosure. Additional features can be added in the FinFET device 200, and some of the features described below can be replaced or eliminated in other embodiments of the semiconductor device 200.

Referring to FIG. 2, the PMOS FinFET device 200 includes a substrate (wafer) 210. The substrate 210 is a bulk silicon substrate. Alternatively, the substrate 210 comprises an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or combinations thereof. Alternatively, the substrate 210 includes a silicon-on-insulator (SOI) substrate. The SOI substrate can be fabricated using separation by implantation of oxygen (SIMOX), wafer bonding, and/or other suitable methods. The substrate 210 may include various doped regions and other suitable features.

The FinFET device 200 includes a 3D structure, such as a fin structure 212, that extends from the substrate 210. The fin structure 212 is formed by a suitable process, such as a lithography and etching process. For example, the fin structure 212 may be formed by forming a photoresist layer (resist) overlying the substrate, exposing the resist to a pattern, performing a post-exposure bake process, and developing the resist to form a masking element including the resist. The masking element may then be used to etch the fin structure 212 into the silicon substrate 210. The fin structure 212 may be etched using a reactive ion etch (RIE) and/or other suitable process. Alternatively, the fin structure 212 is formed by a double-patterning lithography (DPL) process. DPL is a method of constructing a pattern on a substrate by dividing the pattern into two interleaved patterns. DPL allows enhanced feature (e.g., fin) density. Various DPL methodologies may be used including double exposure (e.g., using two mask sets), forming spacers adjacent features and removing the features to provide a pattern of spacers, resist freezing, and/or other suitable processes.

Isolation features 214, such as shallow trench isolation (STI) structures, surround the fin structure 212 and isolate the fin structure 212 from other not-illustrated fins of the FinFET device 200. The isolation features 214 may be formed by partially filling trenches surrounding the fin structure 212 (formed after etching the substrate 210 to form the fin structure 212) with an insulating material, such as silicon oxide, silicon nitride, silicon oxynitride, other suitable material, or combinations thereof. The filled trench may have a multi-layer structure, for example, a thermal oxide liner layer with silicon nitride filling the trench.

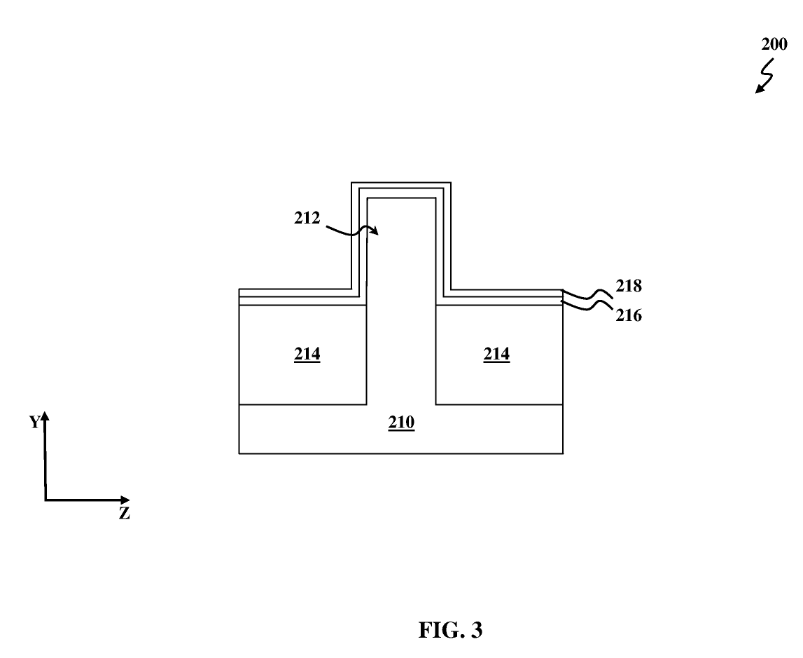

Referring to FIG. 3, a dielectric layer 216 is deposited over a portion of the fin structure 212. The dielectric layer 216 includes a dielectric material, such as silicon oxide, high-k dielectric material, other suitable dielectric material, or combinations thereof. Examples of high-k dielectric material include SiO₂, HfO₂, HfSiO, HfSiON, HfTaO, HfTiO, HfZrO, zirconium oxide, aluminum oxide, hafnium dioxide-alumina (HfO₂—Al₂O₃) alloy, other suitable high-k dielectric materials, and/or combinations thereof. The dielectric layer 216 may be formed having a thickness from about 5 Angstroms to about 30 Angstroms. Formed over the dielectric layer 216 is a work function metal group (WFMG) layer 218. The WFMG layer 218, for example, is a metal including Al, Cu, Ti, Ta, W, Mo, Ni, TaN, NiSi, CoSi, TiN, WN, TiAl, TiAlN, TaCN, TaC, TaSiN, Er, Y, Co, Pd, Pt, other conductive materials, or combinations thereof. As described below, depending on design requirements, the WFMG layer 218 material may be chosen such that it does not react in subsequent reaction process. Also, the WFMG layer 218 may be deposited having a thickness such that even though it may react in subsequent processing, a portion of the WFMG layer 218 will remain. For example, the WFMG may be formed having a thickness from about 5 Angstroms to about 100 Angstroms.

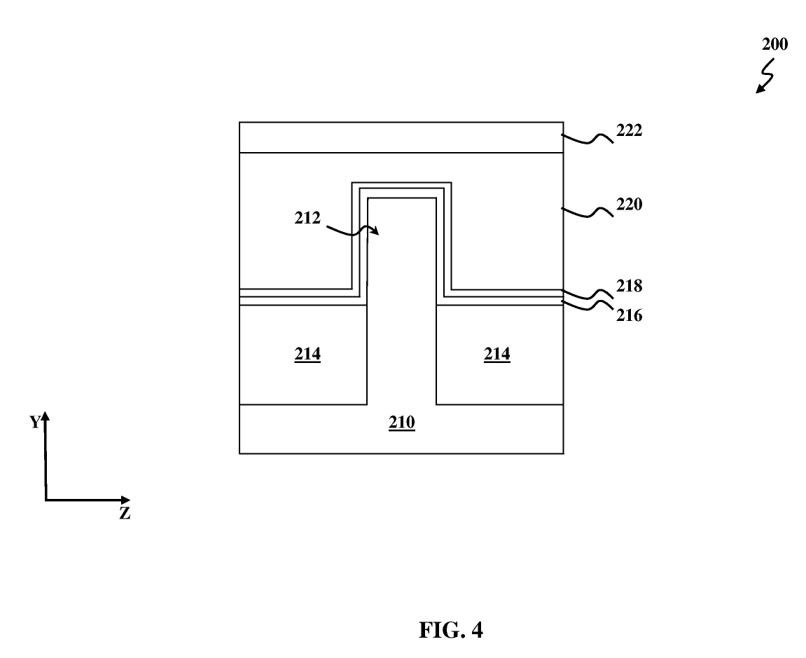

Referring to FIG. 4, a gate structure 220 is formed over the WFMG layer 218. In the present embodiment, the gate structure 220 includes Poly-Si. The Poly-Si material is used in subsequent reaction processes to form a gate structure including silicide. In the present embodiment, the gate structure 220 does not function as a work function metal but rather serves to induce strain in the FinFET device 200 to enhance carrier mobility. In addition, because the gate structure 220 is formed over the WFMG layer 218 rather than directly over the dielectric layer 216, Fermi level pinning effect (i.e., a defect) may be minimized or even eliminated.

The gate structure 220 is formed by a suitable process, including deposition, lithography patterning, and etching processes. The deposition processes include chemical vapor deposition (CVD), physical vapor deposition (PVD), atomic layer deposition (ALD), high density plasma CVD (HDPCVD), metal organic CVD (MOCVD), remote plasma CVD (RPCVD), plasma enhanced CVD (PECVD), low-pressure CVD (LPCVD), atomic layer CVD (ALCVD), atmospheric pressure CVD (APCVD), plating, other suitable methods, or combinations thereof. The lithography patterning processes include photoresist coating (e.g., spin-on coating), soft baking, mask aligning, exposure, post-exposure baking, developing the photoresist, rinsing, drying (e.g., hard baking), other suitable processes, or combinations thereof. Alternatively, the lithography exposing process is implemented or replaced by other methods, such as maskless photolithography, electron-beam writing, and ion-beam writing. In yet another alternative, the lithography patterning process could implement nanoimprint technology. The etching processes include dry etching, wet etching, and/or other etching methods.

Formed over the gate structure 220 is a metal layer 222. The metal layer 222, for example, is a metal including Al, Cu, Ti, Ta, W, Mo, TaN, NiSi, CoSi, TiN, WN, TiAl, TiAlN, TaCN, TaC, TaSiN, Er, Y, Ni, Co, Pd, Pt, other conductive materials, or combinations thereof. As will be further explained below, the metal layer 222 is used in subsequent processing to form silicide. With this in mind, the metal layer 222 material, for example, may be chosen such that it may react with the Poli-Si of the gate structure 220 in a subsequent reaction process while ensuring that the WFMG layer 218 does not react (or has limited reaction). For example, the metal layer 222 may be a metal that has a lower reaction temperature then that of the WFMG layer 218 and thereby allow the metal layer 222 to react while the WFMG layer 218 does not react (or has limited reaction).

Additional thermal process steps can be provided before, during, and after the formation of the gate structure 220 and the formation of the metal layer 222. For example, additional process may include hard mask (HM) deposition, gate patterning, spacer formation, raised source/drain epitaxy (thermal condition from about 450 C to about 800 C), source/drain junction formation (implantation and annealing RTA, laser, flash, SPE, furnace thermal condition from about 550 C to about 1200 C), source/drain silicide formation (thermal condition from about 200 C to about 500 C), hard mask removal, and other suitable process. These additional process steps may produce thermal histories in the FinFET device 200. In certain circumstances, the thermal histories may adversely affect the performance of the FinFET device 200. Accordingly, alternative embodiments, disclosed below, are provided to minimize or even eliminate the thermal history brought about by the additional process steps.

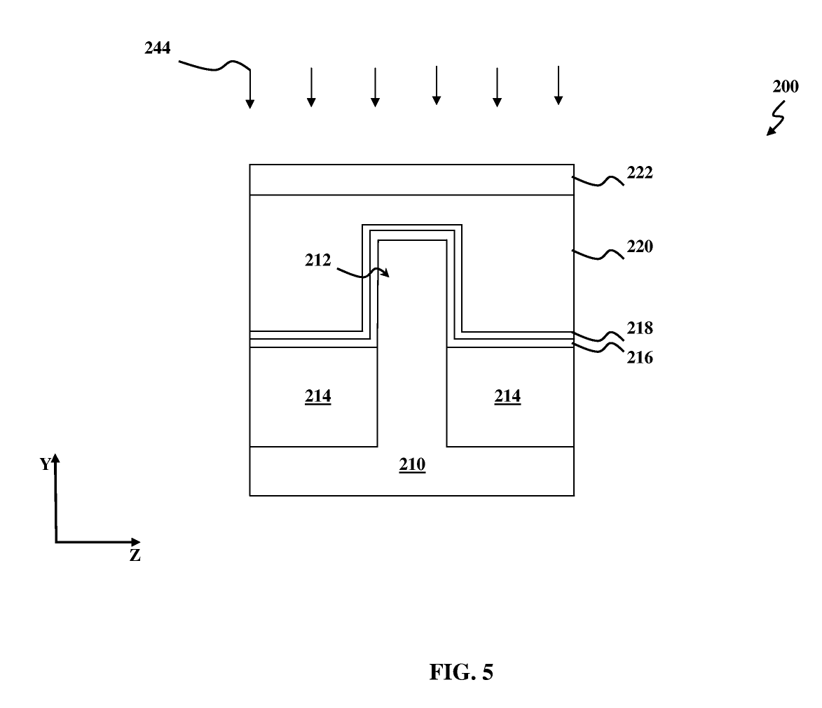

Referring to FIG. 5, a reaction process 224 is performed on the FinFET device 200 to cause a reaction between the Poly-Si of the gate structure 220 and the metal layer 222 such that silicide is formed. After the reaction process 224, the gate structure 220 may include silicide in whole or in part. In other words, after the reaction process 224, all or part of the gate structure 220 may become silicide. The reaction process 224 may be, for example, a process including annealing the metal layer 222 such that the metal layer 222 is able to react with the Poly-Si of the gate structure 220 to form silicide. The reaction process 224 may also include, for example, a high temperature thermal process, a thermal laser process, a ion beam process, a combination thereof, or other suitable process to cause a reaction and thereby form silicide. The formation of silicide causes the volume of the gate structure 220 to change. The volume change may be tuned for a specific FinFET device such as a PMOS or a NMOS FinFET device. The volume may be tuned by either selecting a specific material for the metal layer 222 that has a specific reaction characteristic with the Poly-Si material of the gate structure 220 or by performing the reaction process 224 in such a way that the formed silicide is either metal rich or Si rich. For example, by forming silicide that is metal rich, the gate structure 220 will expand and by forming silicide that is Si rich, the gate structure will shrink. As discussed below, the shrinking of the gate structure 220 will induce a stress in the fin structure 212 and thereby enhance performance of a PMOS FinFET device while the expanding of the gate structure 220 will induce a stress in the fin structure 212 and thereby enhance performance of a NMOS FinFET device. In the present embodiment, the volume change is tuned such that the gate structure 220 shrinks (e.g., Si rich) thereby enhancing electron mobility in the PMOS FinFET device 200.

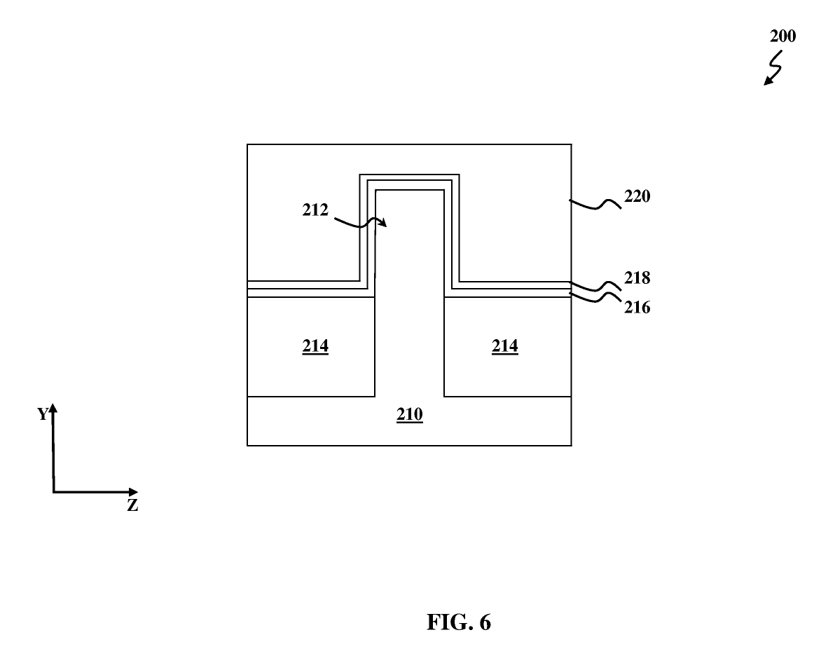

Referring to FIG. 6, after the reaction process 224, portions of the metal layer 222 that have not reacted are removed. The non-reacted metal layer 222 may be removed by any suitable process. For example, in the present embodiment, the non-reacted metal layer 222 is removed by an etching process. The etching process may include a wet etching or dry etching process, or a combination thereof.

Referring back to FIG. 4, in alternative embodiments, the gate structure 220 does not include Poly-Si. In such embodiments the gate structure 220 includes a metal, for example, a metal including Al, Cu, Ti, Ta, W, Mo, TaN, NiSi, CoSi, TiN, WN, TiAl, TiAlN, TaCN, TaC, TaSiN, Er, Y, Ni, Co, Pd, Pt, or combinations thereof. Also, in such embodiments, the metal layer 222 is also not formed over the gate structure 220. Rather, after the gate structure 220 including a metal is formed, an implantation process may be performed to implant the metal of the gate structure 220 with Si, or other impurities, and thereby create a gate structure 220 including silicide.

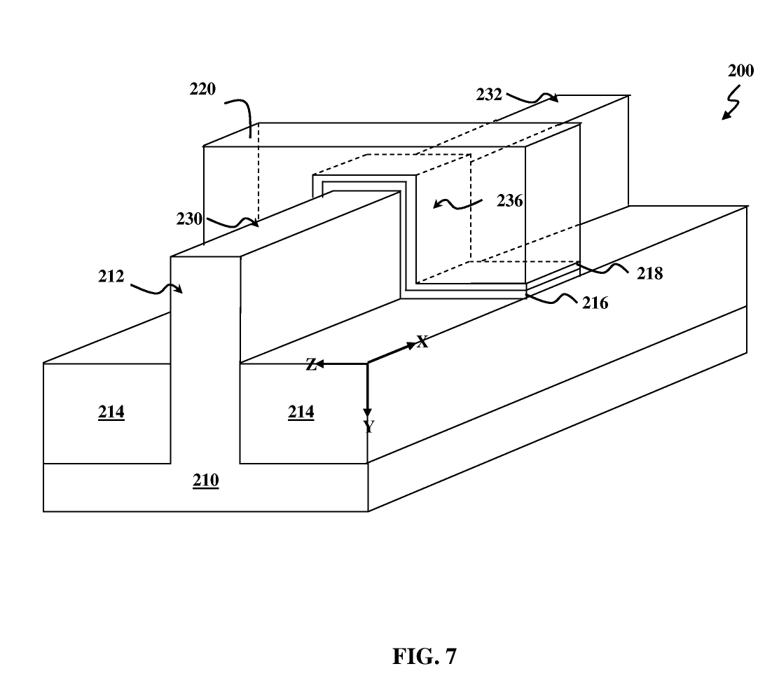

FIG. 7 illustrates a perspective view of the FinFET device 200 at one stage of fabrication. As can be seen, the FinFET device 200 includes a substrate 210 that includes a fin structure 212. The fin structure 212 includes a source region 230 a drain region 232 and a channel region 236 (between the source region 230 and drain region 232). The FinFET device 200 further includes the gate structure 220 disposed over the channel region 236 of the fin structure 212. The FinFET device 200 may include additional features, which may be formed by subsequent processing. For example, various contacts/vias/lines and multilayer interconnect features (e.g., metal layers and interlayer dielectrics) may be formed over the substrate 210, configured to connect the various features or structures of the FinFET device 200. The additional features may provide electrical interconnection to the device 200. For example, a multilayer interconnection includes vertical interconnects, such as conventional vias or contacts, and horizontal interconnects, such as metal lines. The various interconnection features may implement various conductive materials including copper, tungsten, and/or silicide. In one example, a damascene and/or dual damascene process is used to form a copper related multilayer interconnection structure.

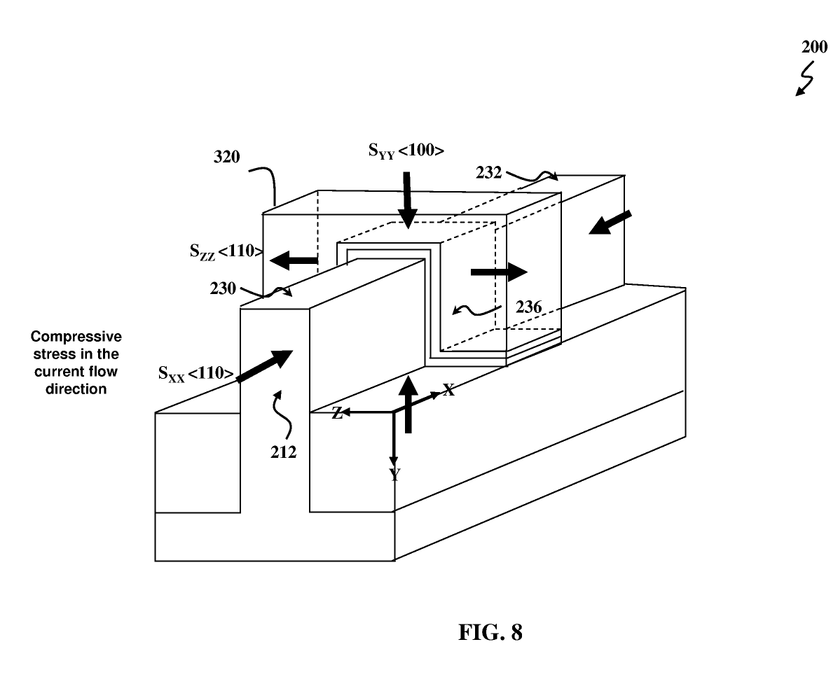

FIG. 8 illustrates a partial perspective view of one embodiment of the PMOS FinFET device 200 and the direction of stress forces. The FinFET device 200 experiences enhanced carrier mobility when the gate structure 220 shrinks and induces compressive stress in the current flow direction of the channel region 236. For example, when the gate structure 220 shrinks, the gate structure 220 induces a tensile stress in the Szz 110 direction, a compressive stress in the Syy 100 direction and a compressive stress in the Sxx 110 direction (the current flow direction) of the channel region 236, and thereby enhances the carrier mobility of the PMOS FinFET device 200. In addition, as note above, because the gate structure 220 is formed over the WFMG layer 218 rather than directly over the dielectric layer 216, Fermi level pinning effect (i.e., a defect) may be minimized or even eliminated. Further, the method 100 disclosed herein is easily implemented into current processing. It is understood that different embodiments may have different advantages, and no particular advantage is necessarily required of any embodiment.

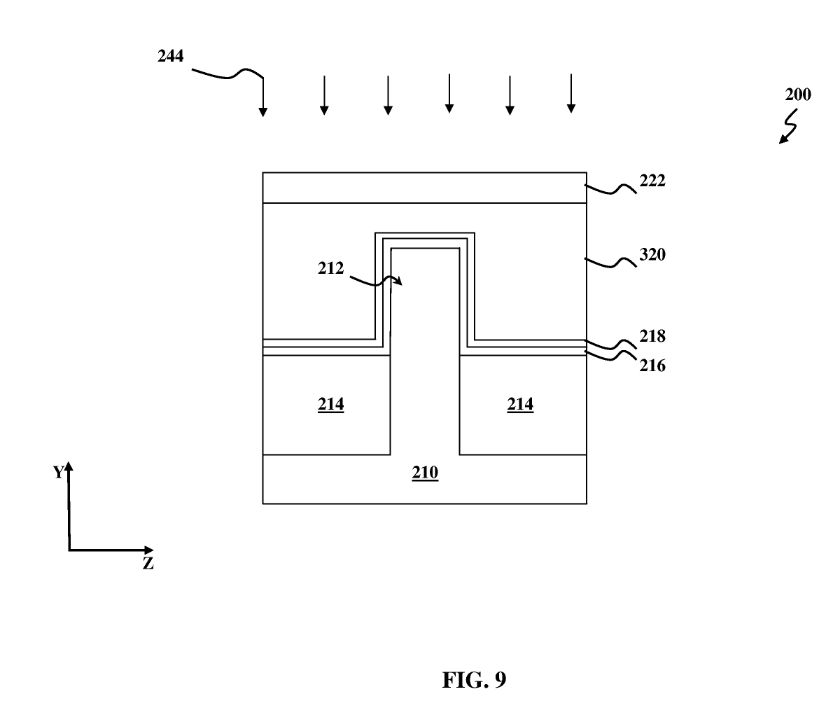

FIG. 9-11 provide various views of another FinFET device 300, in portion or entirety, at various stages of fabrication according to the method 100 of FIG. 1. The FinFET device 300 may be included in a microprocessor, memory cell, and/or other integrated circuit device. In the depicted embodiment, the FinFET device 300 is an N-type metal-oxide-semiconductor (NMOS) FinFET device. The NMOS FinFET device 300 of FIGS. 9-11 is similar in many respects to the PMOS FinFET device 200 of FIGS. 2-8. Accordingly, similar features in FIGS. 2-8 and 9-11 are identified by the same reference numerals for clarity and simplicity. FIGS. 9-11 have been simplified for the sake of clarity to better understand the inventive concepts of the present disclosure. Additional features can be added in the FinFET device 300, and some of the features described below can be replaced or eliminated in other embodiments of the FinFET device 300.

FIG. 9 is a cross-sectional side view of one embodiment of the FinFET device 300. The FinFET device 300 includes a substrate 210, a fin structure 212, isolation features 214, a dielectric layer 216, WFMG 218, a gate structure 320 including Poly-Si, and a metal layer 222. In contrast to the FinFET device 200 of FIGS. 2-8, in the depicted embodiment, the reactive process 224 is tuned such that it produces a reaction between the metal layer 222 and the Poly-Si of the gate structure 320 to form silicide that is metal rich; thereby expanding he gate structure 320 and inducing stress in the channel region of the NMOS FinFET device 300.

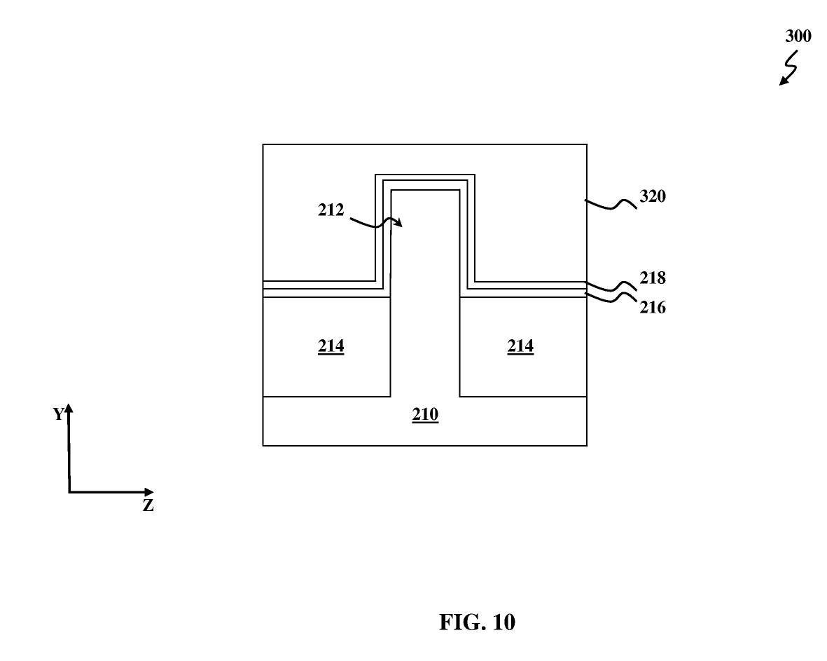

Referring to FIG. 10, after the reaction process 224, portions of the metal layer 222 that have not reacted are removed. The non-reacted metal layer 222 may be removed by any suitable process.

The FinFET device 300 may include additional features, which may be formed by subsequent processing. For example, various contacts/vias/lines and multilayer interconnect features (e.g., metal layers and interlayer dielectrics) may be formed over the substrate 210, configured to connect the various features or structures of the FinFET device 300. The additional features may provide electrical interconnection to the device 300. For example, a multilayer interconnection includes vertical interconnects, such as conventional vias or contacts, and horizontal interconnects, such as metal lines. The various interconnection features may implement various conductive materials including copper, tungsten, and/or silicide. In one example, a damascene and/or dual damascene process is used to form a copper related multilayer interconnection structure.

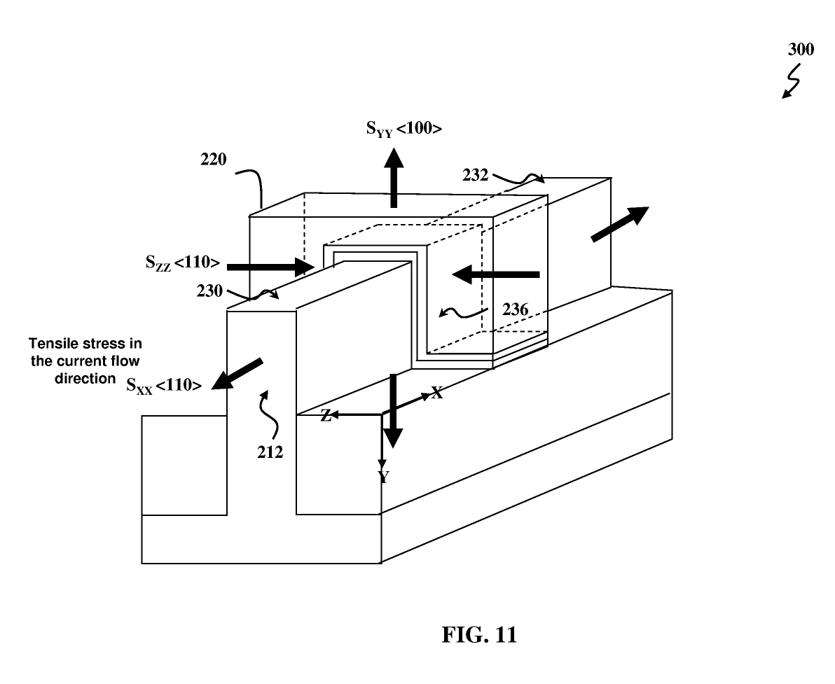

FIG. 11 illustrates a partial perspective view of one embodiment of the NMOS FinFET device 300 and the direction of stress forces. The FinFET device 300 experiences enhanced carrier mobility when the gate structure 320 expands and induces tensile stress in the current flow direction of the channel region. For example, when the gate structure 320 expands, the gate structure 320 induces a compressive stress in the Szz 110 direction, a tensile stress in the Syy 100 direction and a tensile stress in the Sxx 110 direction (the current flow direction) of the channel region 236, and thereby enhances the carrier mobility of the NMOS FinFET device 300. In addition, as note above, because the gate structure 220 is formed over the WFMG layer 218 rather than directly over the dielectric layer 216, Fermi level pinning effect (i.e., a defect) may be minimized or even eliminated. Further, the method 100 disclosed herein is easily implemented into current processing. It is understood that different embodiments may have different advantages, and no particular advantage is necessarily required of any embodiment.

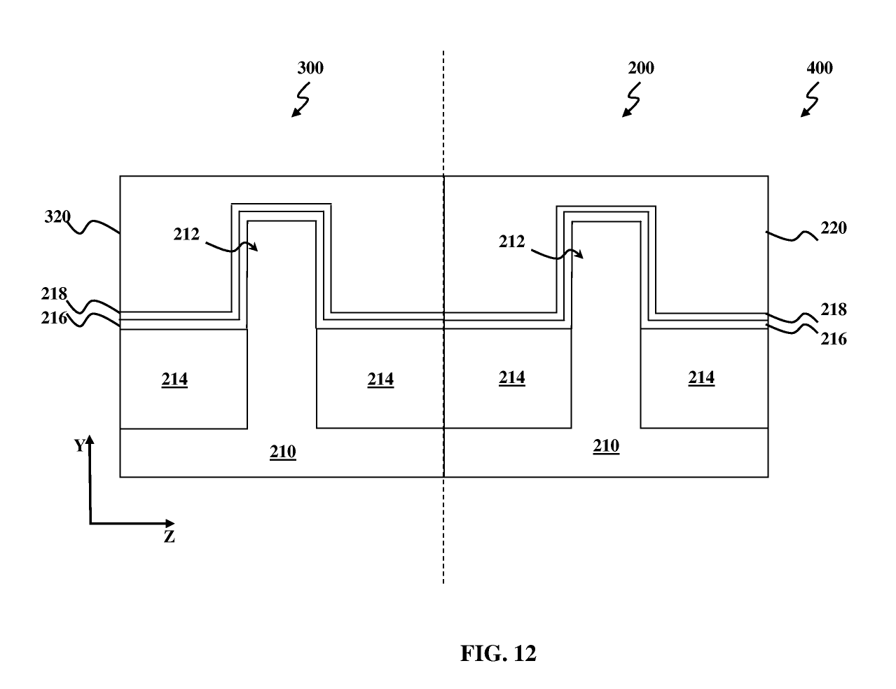

The PMOS FinFET device 200 and NMOS FinFET device 300 can be fabricated in a single integrated circuit device using the method 100. FIG. 12 illustrates a integrated circuit device 400. The integrated circuit device 400 may be included in a microprocessor, memory cell, and/or other integrated circuit device. The integrated circuit device 400 includes the FinFET device 200 (of FIGS. 2-8) and the FinFET device 300 (of FIGS. 9-11). The integrated circuit device 400 is similar in many respects to the FinFET device 200, 300 of FIGS. 2-11. Accordingly, similar features in FIGS. 2-11 and FIG. 12 are identified by the same reference numerals for clarity and simplicity. FIG. 12 has been simplified for the sake of clarity to better understand the inventive concepts of the present disclosure. Additional features can be added in the FinFET integrated circuit device 400, and some of the features described below can be replaced or eliminated in other embodiments of the FinFET device 400.

The integrated circuit device 400 may include additional features, which may be formed by subsequent processing. For example, various contacts/vias/lines and multilayer interconnect features (e.g., metal layers and interlayer dielectrics) may be formed over the substrate 210, configured to connect the various features or structures of the integrated circuit device 400. The additional features may provide electrical interconnection to the device 400. For example, a multilayer interconnection includes vertical interconnects, such as conventional vias or contacts, and horizontal interconnects, such as metal lines. The various interconnection features may implement various conductive materials including copper, tungsten, and/or silicide. In one example, a damascene and/or dual damascene process is used to form a copper related multilayer interconnection structure.

The integrated circuit device 400 includes similar strain characteristics as that of the FinFET device 200 and 300. Accordingly, the integrated circuit device 400 benefits from the disclosed embodiment of method 100 by enhancing carrier mobility when the gate structure 220 of the PMOS device 200 shrinks and induces compressive stress in the current flow direction of the channel region 236 and when the gate structure 320 of the NMOS device 300 expands and induces tensile stress in the current flow direction of the channel region 236. In addition, as note above, because the gate structure 220 is formed over the WFMG layer 218 rather than directly over the dielectric layer 216, Fermi level pinning effect (i.e., a defect) may be minimized or even eliminated. Further, the method 100 disclosed herein is easily implemented into current processing. It is understood that different embodiments may have different advantages, and no particular advantage is necessarily required of any embodiment.

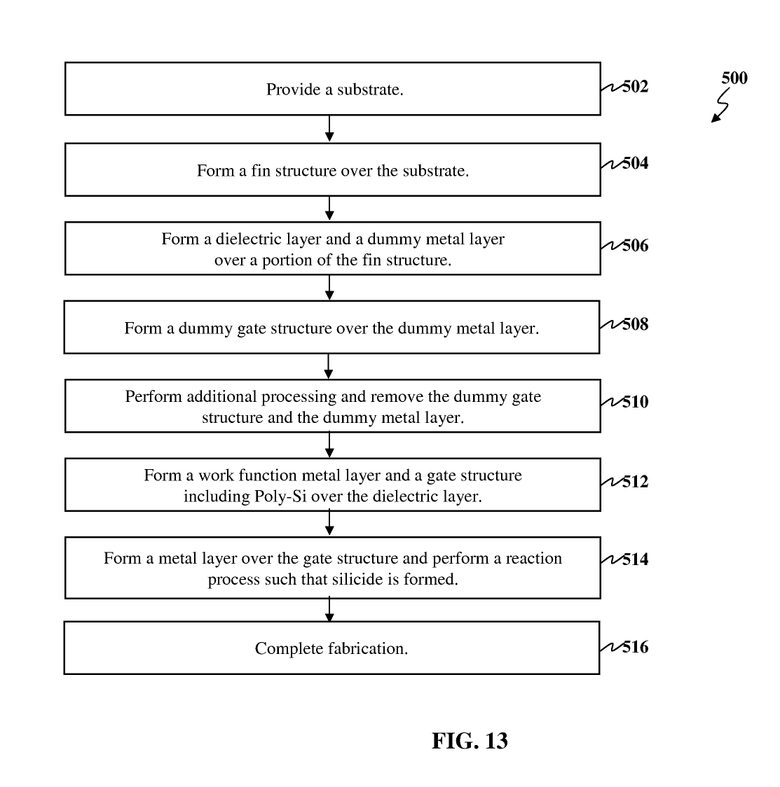

Referring to FIG. 13, a method 500 for fabricating a semiconductor device is described according to various aspects of the present disclosure. The embodiment of method 500 may include similar process steps as an embodiment of the method 100 which is disclosed above. In disclosing the embodiment of method 500, some details regarding processing and/or structure may be skipped for simplicity if they are similar to those described in the embodiment of method 100. The method 500 begins at block 502 in which a substrate is provided. At blocks 504 and 506, a fin structure is formed over the substrate, and a dielectric layer and a dummy metal layer are formed over a portion of the fin structure. As disclosed below, the dummy metal layer is an optional layer. At block 508, a dummy gate structure is formed over the dummy metal layer. The method continues with block 510 where additional processing is performed and thereafter the dummy gate structure and the dummy metal layer are removed. The additional processing includes a thermal process. At block 512, a work function metal layer is formed over the dielectric layer and a gate structure is formed over the work function metal layer. At block 514, a metal layer is formed over the gate structure and a reaction process is performed between the gate structure and the metal layer such that silicide is formed. The method 500 continues with block 516 where fabrication of the integrated circuit device is completed. Additional steps can be provided before, during, and after the method 500, and some of the steps described can be replaced or eliminated for other embodiments of the method. The discussion that follows illustrates various embodiments of an integrated circuit device that can be fabricated according to the method 500 of FIG. 13.

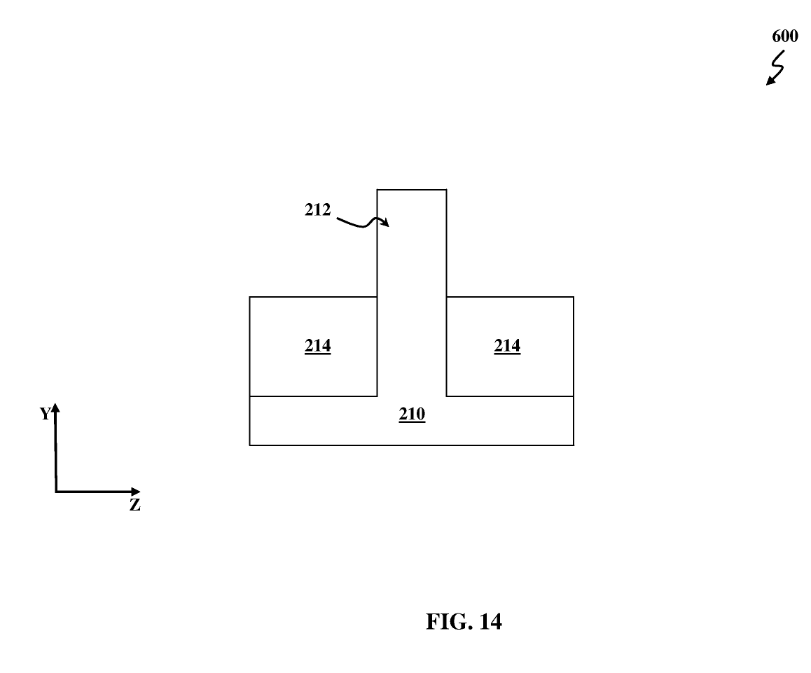

FIGS. 14 to 20 illustrate diagrammatic cross-sectional side views of one embodiment of a semiconductor device 600 at various stages of fabrication according to the method 500 of FIG. 13. The semiconductor device 600 of FIGS. 14-20 is similar in certain respects to the semiconductor device 200, 300, and 400 of FIGS. 2-8, 9-11, and 12. Thus, similar features in FIGS. 2-12 and FIGS. 14-20 are identified by the same reference numerals for clarity and simplicity. FIGS. 14-20 have been simplified for the sake of clarity to better understand the inventive concepts of the present disclosure. In the present disclosure, the semiconductor device 600 is implemented as a FinFET device. The FinFET device 600 may be included in a microprocessor, memory cell, and/or other integrated circuit device. Additional features can be added in the FinFET device 600, and some of the features described below can be replaced or eliminated in other embodiments of the semiconductor device 600.

Referring to FIG. 14, the FinFET device 600 includes a substrate 210. In the present embodiment, the substrate 210 defined in the FinFET device 600 is substantially similar to the substrate 210 of the FinFET device 200 in terms of composition, formation and configuration. In an alternative embodiment, they are different. The FinFET device 600 further includes a fin structure 212. In the present embodiment, the fin structure 212 defined in the FinFET device 600 is substantially similar to the fin structure 212 of the FinFET device 200 in terms of composition, formation and configuration. In an alternative embodiment, they are different. The FinFET device 600 further includes isolation features 214. In the present embodiment, isolation features 214 defined in the FinFET device 600 are substantially similar to the isolation features 214 of the FinFET device 200 in terms of composition, formation and configuration. In an alternative embodiment, they are different.

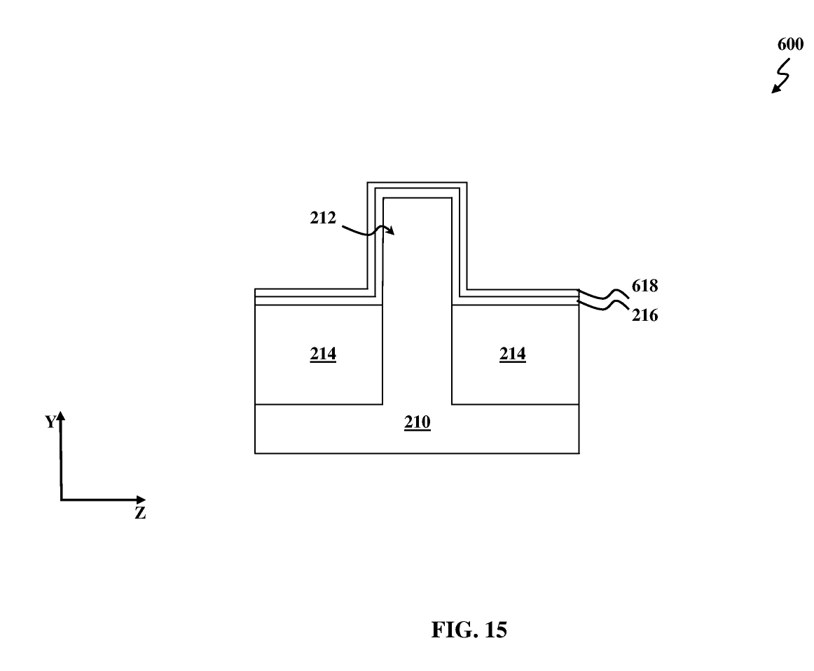

Referring to FIG. 15, the FinFET device 600 includes a dielectric layer 216. In the present embodiment, the dielectric layer 216 defined in the semiconductor device 600 is substantially similar to the dielectric layer 216 of the semiconductor device 200 in terms of composition, formation and configuration. In an alternative embodiment, they are different. The FinFET device 600 also includes a dummy metal layer 618. The dummy metal layer 618 may include a metal such as Al, Cu, Ti, Ta, W, Mo, Ni, TaN, NiSi, CoSi, TiN, WN, TiAl, TiAlN, TaCN, TaC, TaSiN, Er, Y, Co, Pd, Pt, other conductive materials, or combinations thereof.

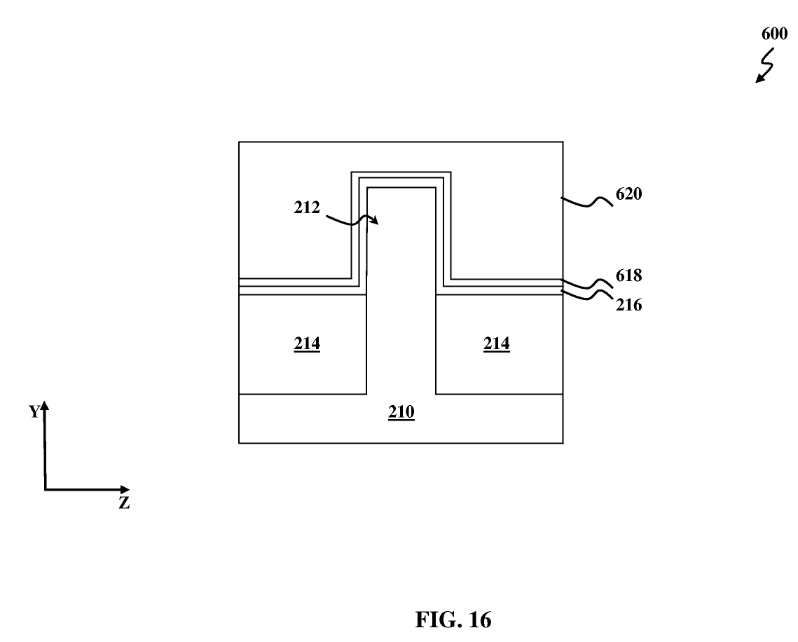

Referring to FIG. 16, formed over dummy metal layer 618 is a dummy gate structure 620. The dummy gate structure 620 may include any suitable material. For example, in the present embodiment, the dummy gate structure 620 includes Si. In the present embodiment, the dummy gate structure 620 is not a final gate structure but rather serves as a sacrificial structure that protects various material layers and device regions in subsequent processing. The dummy gate structure 620 is formed by a suitable process, including deposition, lithography patterning, and etching processes. The deposition processes include chemical vapor deposition (CVD), physical vapor deposition (PVD), atomic layer deposition (ALD), high density plasma CVD (HDPCVD), metal organic CVD (MOCVD), remote plasma CVD (RPCVD), plasma enhanced CVD (PECVD), low-pressure CVD (LPCVD), atomic layer CVD (ALCVD), atmospheric pressure CVD (APCVD), plating, other suitable methods, or combinations thereof. The lithography patterning processes include photoresist coating (e.g., spin-on coating), soft baking, mask aligning, exposure, post-exposure baking, developing the photoresist, rinsing, drying (e.g., hard baking), other suitable processes, or combinations thereof. Alternatively, the lithography exposing process is implemented or replaced by other methods, such as maskless photolithography, electron-beam writing, and ion-beam writing. In yet another alternative, the lithography patterning process could implement nanoimprint technology. The etching processes include dry etching, wet etching, and/or other etching methods.

Additional heat inducing process steps can be provided before, during or after the formation of the dummy gate structure 620. For example, additional process may include hard mask (HM) deposition, gate patterning, spacer formation, raised source/drain epitaxy (thermal condition from about 450 C to about 800 C), source/drain junction formation (implantation and annealing RTA, laser, flash, SPE, furnace thermal condition from about 550 C to about 1200 C), source/drain silicide formation (thermal condition from about 200 C to about 500 C), hard mask removal, and other suitable process. These additional process steps may produce thermal histories in various layers/structures of the FinFET device 600. In certain circumstances, the thermal histories may adversely affect the performance of the FinFET device 600. However, because the method 500 employs a dummy metal layer 618 and a dummy gate structure 620, these layer/structure will subsequently be removed thereby reducing the thermal history of the final WFMG and gate structure. Accordingly, as to certain layers/structures, the embodiment of method 500 serves minimize or even eliminate the thermal history brought about by the additional heat inducing process steps.

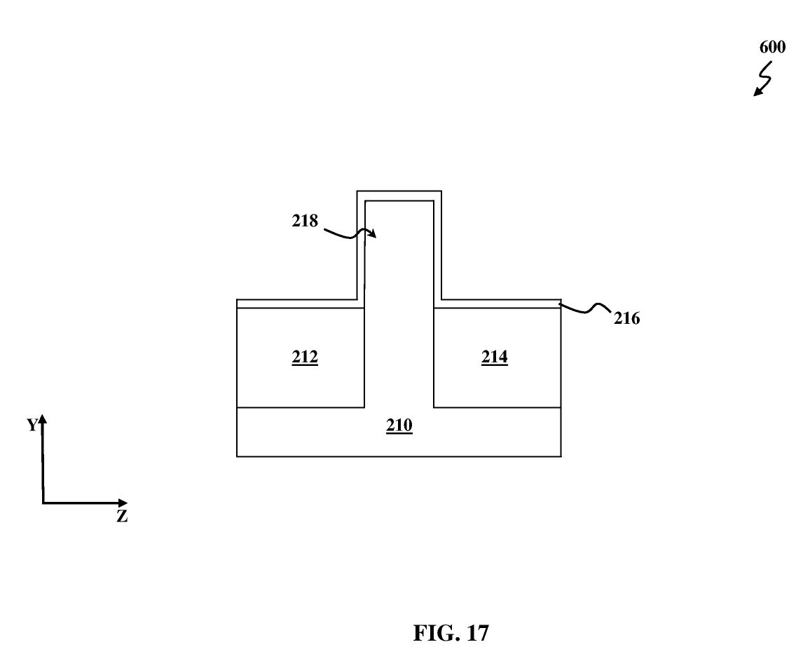

Referring to FIG. 17, after the heat inducing process steps are performed, the dummy gate structure 620 and dummy metal layer 618 are removed. The dummy gate structure 620 and dummy metal layer 618 may be removed by any suitable process. For example, dummy gate structure 620 and the dummy metal layer 618 may be removed by an etching process. The etching process may include a wet etching or dry etching process, or a combination thereof. In one example, wet etching process using hydrofluoric acid (HF) or buffered HF may be used. In furtherance of the example, the chemistry of the wet etching includes TMAH, NH4OH, and other suitable chemistries. In one example, a dry etching process includes a chemistry including fluorine-containing gas. In furtherance of the example, the chemistry of the dry etch includes CF4, SF6, or NF3.

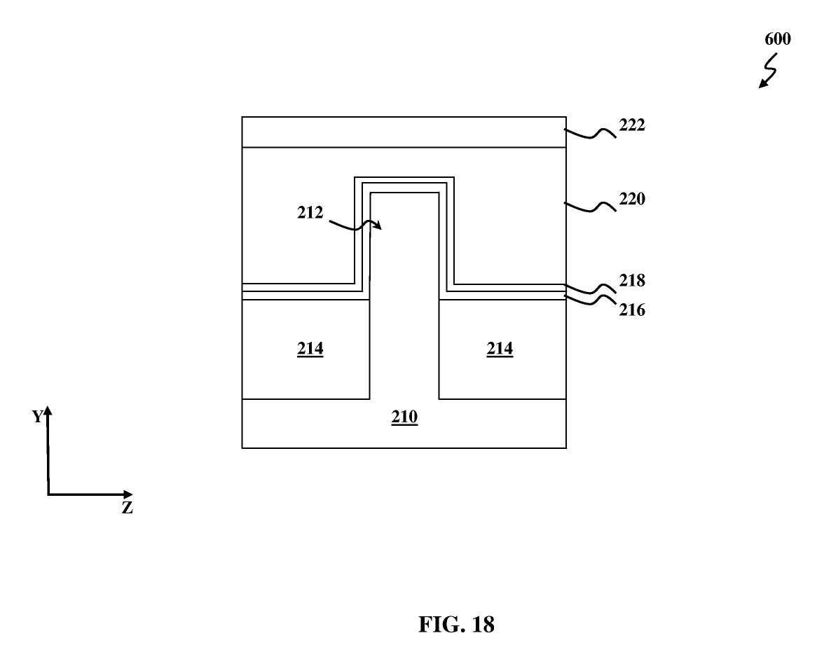

Referring to FIG. 18, after the removal step, a WFMG layer 218 is formed over the dielectric layer 216. In the present embodiment, the WFMG layer 218 defined in the FinFET device 600 is substantially similar to the WFMG layer 218 of the FinFET device 200 in terms of composition, formation and configuration. In an alternative embodiment, they are different. Formed over the WFMG layer 218 is a gate structure 220. In the present embodiment, the gate structure 220 defined in the FinFET device 600 is substantially similar to the gate structure 220 of the FinFET device 200 in terms of composition, formation and configuration. In an alternative embodiment, they are different. Formed over the gate structure 220 is a metal layer 222. In the present embodiment, the metal layer 222 defined in the FinFET device 600 is substantially similar to the metal layer 222 of the FinFET device 200 in terms of composition, formation and configuration. In an alternative embodiment, they are different.

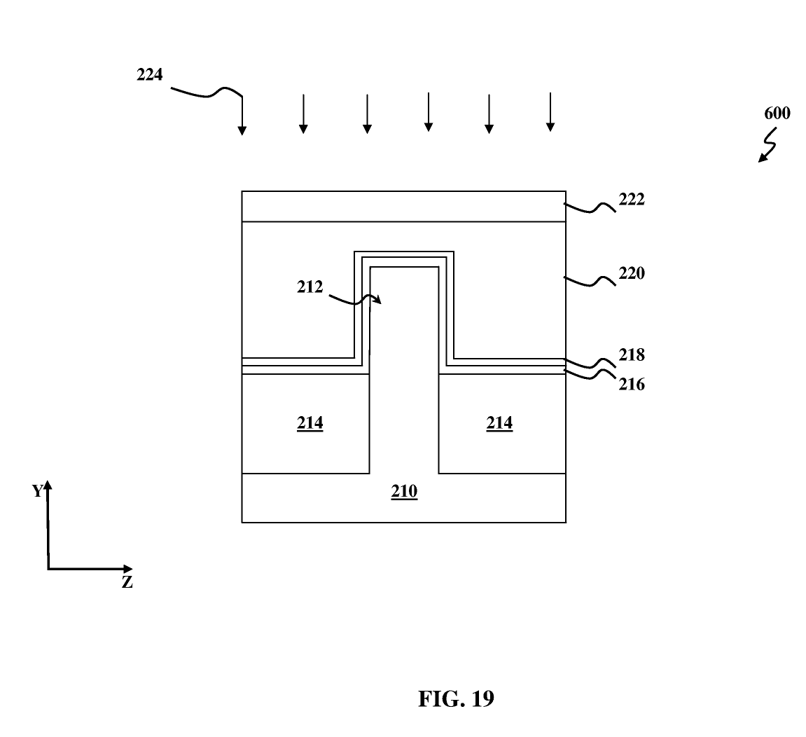

Referring to FIG. 19, a reaction process 224 is performed on the FinFET device 600 to cause a reaction between the Poly-Si of the gate structure 220 and the metal layer 222 such that silicide is formed. In the present embodiment, the reaction process 224 of FIG. 19 is substantially similar to the reaction process 224 of FIG. 5. In an alternative embodiment, they are different.

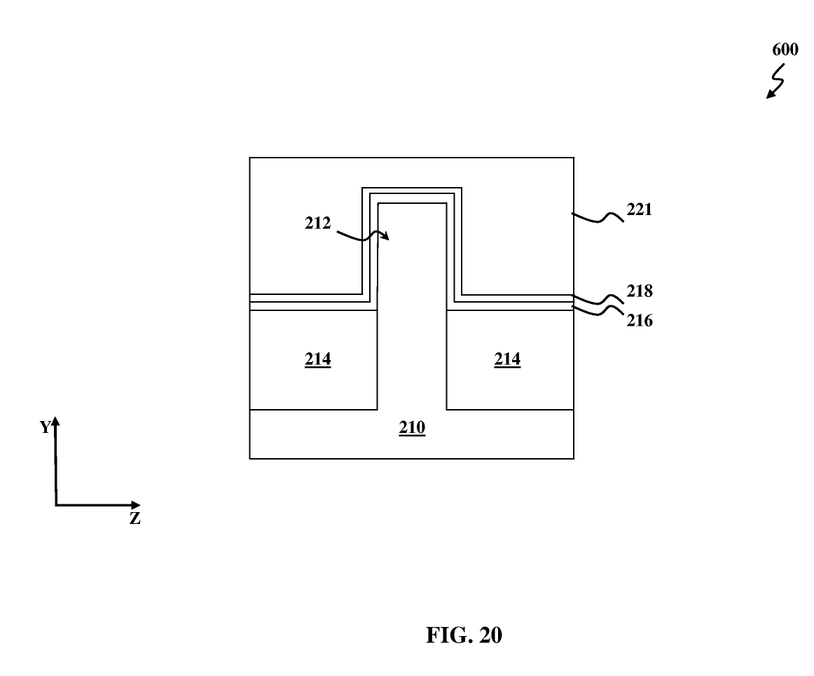

Referring to FIG. 20, after the reaction process 224, portions of the metal layer 222 that have not reacted are removed. The non-reacted metal layer 222 may be removed by any suitable process. For example, in the present embodiment, the non-reacted metal layer 222 is removed by an etching process. The etching process may include a wet etching or dry etching process, or a combination thereof.

With further reference to FIGS. 13-20, as noted above, the dummy metal layer 618 is an optional layer. Accordingly, in embodiments where the dummy metal layer 618 is not present, a WFMG layer 218 is formed over the dielectric layer 216 and thereafter a dummy gate structure 620 is formed over the WFMG layer 218. After the dummy gate structure 620 is formed, a heat inducing process is performed. And, thereafter, the dummy gate structure 620 is removed by any suitable process. After the dummy gate structure 620 is removed, a gate structure 221 is formed over the WFMG 218 and a reaction process is performed such that silicide is formed.

The FinFET device 600 of method 500 may be implemented as a PMOS FinFET device or a NMOS FinFET device. Further, the PMOS and NMOS FinFET device 600 can be fabricated in a single integrated circuit device using the method 500. The FinFET device 600 may include additional features, which may be formed by subsequent processing. For example, various contacts/vias/lines and multilayer interconnect features (e.g., metal layers and interlayer dielectrics) may be formed over the substrate 210, configured to connect the various features or structures of the FinFET device 600. The additional features may provide electrical interconnection to the device 600. For example, a multilayer interconnection includes vertical interconnects, such as conventional vias or contacts, and horizontal interconnects, such as metal lines. The various interconnection features may implement various conductive materials including copper, tungsten, and/or silicide. In one example, a damascene and/or dual damascene process is used to form a copper related multilayer interconnection structure.

The FinFET device 600 includes similar strain characteristics as that of the FinFET device 200 and 300. Accordingly, the FinFET device 600 benefits from the disclosed embodiment of method 500 by enhancing carrier mobility Also, FinFET device 600 benefits from the embodiment of method 500 by having a lower thermal history. In addition, as note above, because the gate structure 220 is formed over the WFMG layer 218 rather than directly over the dielectric layer 216, Fermi level pinning effect (i.e., a defect) may be minimized or even eliminated. Further, the method 500 disclosed herein is easily implemented into current processing. It is understood that different embodiments may have different advantages, and no particular advantage is necessarily required of any embodiment.

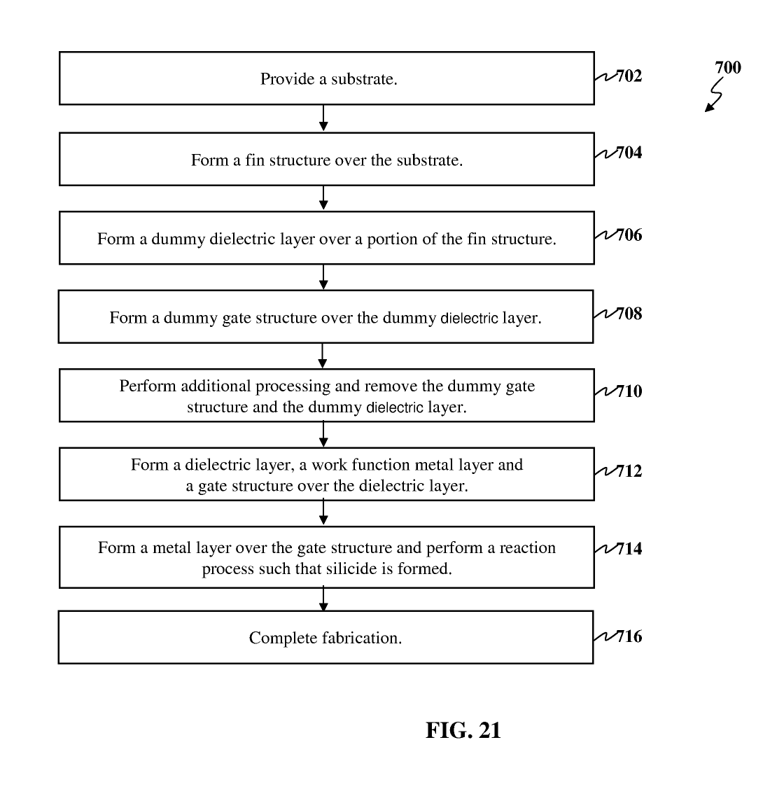

Referring to FIG. 21, a method 700 for fabricating a semiconductor device is described according to various aspects of the present disclosure. The embodiment of method 700 may include similar process steps as an embodiment of the method 100 which is disclosed above. In disclosing the embodiment of method 700, some details regarding processing and/or structure may be skipped for simplicity if they are similar to those described in the embodiment of method 100. The method 700 begins at block 702 in which a substrate is provided. At blocks 704 and 706, a fin structure is formed over the substrate, and a dummy dielectric layer is formed over a portion of the fin structure. At block 708, a dummy gate structure is formed over the dummy dielectric layer. The method continues with block 710 where additional processing is performed and thereafter the dummy gate structure and the dummy dielectric layer are removed. At block 712, a dielectric layer, a work function metal layer and a gate structure are formed over the dielectric layer. At block 714, a metal layer is formed over the gate structure and a reaction process is performed between the gate structure and the metal layer such that silicide is formed. The method 700 continues with block 716 where fabrication of the integrated circuit device is completed. Additional steps can be provided before, during, and after the method 700, and some of the steps described can be replaced or eliminated for other embodiments of the method. The discussion that follows illustrates various embodiments of an integrated circuit device that can be fabricated according to the method 700 of FIG. 21.

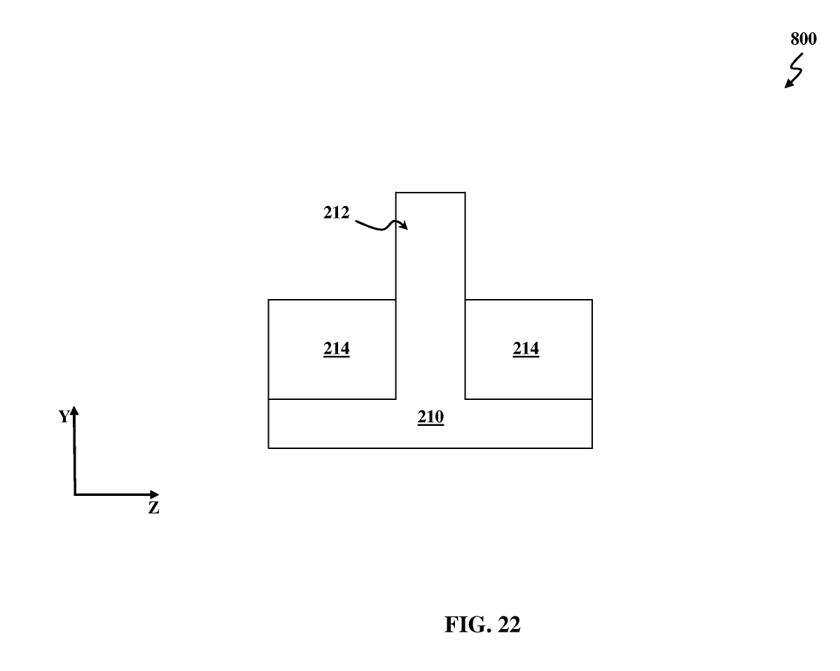

FIGS. 22 to 28 illustrate diagrammatic cross-sectional side views of one embodiment of a semiconductor device 800 at various stages of fabrication according to the method 700 of FIG. 21. The semiconductor device 800 of FIGS. 22-28 is similar in certain respects to the semiconductor device 200, 300, and 400 of FIGS. 2-8, 9-11, and 12. Accordingly, similar features in FIGS. 2-12 and FIGS. 22-28 are identified by the same reference numerals for clarity and simplicity. FIGS. 22-28 have been simplified for the sake of clarity to better understand the inventive concepts of the present disclosure. In the present disclosure, the semiconductor device 800 is implemented as a FinFET device. The FinFET device 800 may be included in a microprocessor, memory cell, and/or other integrated circuit device. Additional features can be added in the FinFET device 800, and some of the features described below can be replaced or eliminated in other embodiments of the semiconductor device 800.

Referring to FIG. 22, the FinFET device 800 includes a substrate 210. In the present embodiment, the substrate 210 defined in the FinFET device 800 is substantially similar to the substrate 210 of the FinFET device 200 in terms of composition, formation and configuration. In an alternative embodiment, they are different. The FinFET device 800 further includes a fin structure 212. In the present embodiment, the fin structure 212 defined in the FinFET device 800 is substantially similar to the fin structure 212 of the FinFET device 200 in terms of composition, formation and configuration. In an alternative embodiment, they are different. The FinFET device 800 further includes isolation features 214. In the present embodiment, isolation features 214 defined in the FinFET device 800 are substantially similar to the isolation features 214 of the FinFET device 200 in terms of composition, formation and configuration. In an alternative embodiment, they are different.

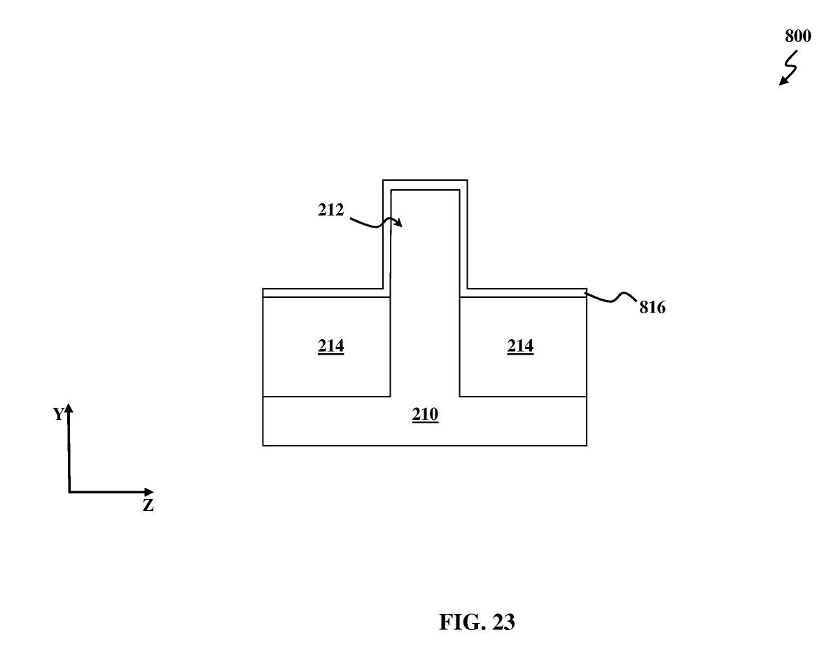

Referring to FIG. 23, the FinFET device 800 includes a dummy dielectric layer 816. The dummy dielectric layer 816 includes a dielectric material, such as silicon oxide, high-k dielectric material, other suitable dielectric material, or combinations thereof. Examples of high-k dielectric material include SiO₂, HfO₂, HfSiO, HfSiON, HfTaO, HfTiO, HfZrO, zirconium oxide, aluminum oxide, hafnium dioxide-alumina (HfO₂—Al₂O₃) alloy, other suitable high-k dielectric materials, and/or combinations thereof.

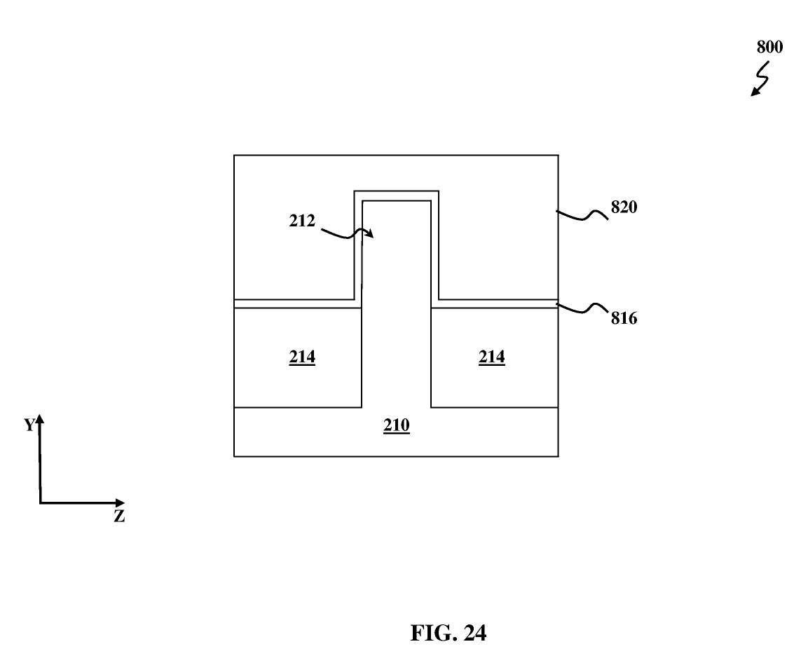

Referring to FIG. 24, formed over dummy dielectric layer 816 is a dummy gate structure 820. The dummy gate structure 820 may include any suitable material. For example, in the present embodiment, the dummy gate structure 820 includes Si. In the present embodiment, the dummy gate structure 820 is not a final gate structure but rather serves as a sacrificial structure that protects various material layers and device regions in subsequent processing. The dummy gate structure 820 is formed by a suitable process, including deposition, lithography patterning, and etching processes. The deposition processes include chemical vapor deposition (CVD), physical vapor deposition (PVD), atomic layer deposition (ALD), high density plasma CVD (HDPCVD), metal organic CVD (MOCVD), remote plasma CVD (RPCVD), plasma enhanced CVD (PECVD), low-pressure CVD (LPCVD), atomic layer CVD (ALCVD), atmospheric pressure CVD (APCVD), plating, other suitable methods, or combinations thereof. The lithography patterning processes include photoresist coating (e.g., spin-on coating), soft baking, mask aligning, exposure, post-exposure baking, developing the photoresist, rinsing, drying (e.g., hard baking), other suitable processes, or combinations thereof. Alternatively, the lithography exposing process is implemented or replaced by other methods, such as maskless photolithography, electron-beam writing, and ion-beam writing. In yet another alternative, the lithography patterning process could implement nanoimprint technology. The etching processes include dry etching, wet etching, and/or other etching methods.

Additional heat inducing process steps can be provided during or after the formation of the dummy gate structure 820. For example, additional process may include hard mask (HM) deposition, gate patterning, spacer formation, raised source/drain epitaxy (thermal condition from about 450 C to about 800 C), source/drain junction formation (implantation and annealing RTA, laser, flash, SPE, furnace thermal condition from about 550 C to about 1200 C), source/drain silicide formation (thermal condition from about 200 C to about 500 C), hard mask removal, and other suitable process. These additional process steps may produce thermal histories in various layers/structures of the FinFET device 800. In certain circumstances, the thermal histories may adversely affect the performance of the FinFET device 800. However, because the method 700 employs a dummy dielectric layer 816 and a dummy gate structure 820, these layer/structure will subsequently be removed thereby reducing the thermal history of the final device. Accordingly, as to certain layers/structures, the embodiment of method 700 serves minimize or even eliminate the thermal history brought about by the additional heat inducing process steps.

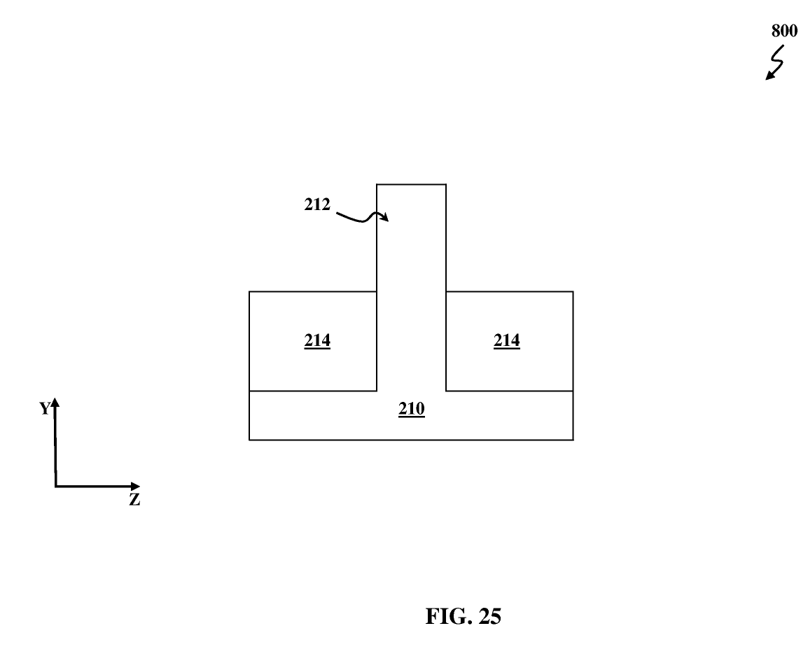

Referring to FIG. 25, after the heat inducing process steps are performed, the dummy gate structure 820 and dummy dielectric layer 816 are removed. The dummy gate structure 820 and dummy dielectric layer 816 may be removed by any suitable process. For example, an etching process may be used to remove the dummy gate structure 820 and dummy dielectric layer 816. The etching process may include a wet etching or dry etching process, or a combination thereof. In one example, wet etching process using hydrofluoric acid (HF) or buffered HF may be used. In furtherance of the example, the chemistry of the wet etching includes TMAH, NH4OH, and other suitable chemistries. In one example, a dry etching process includes a chemistry including fluorine-containing gas. In furtherance of the example, the chemistry of the dry etch includes CF4, SF6, or NF3.

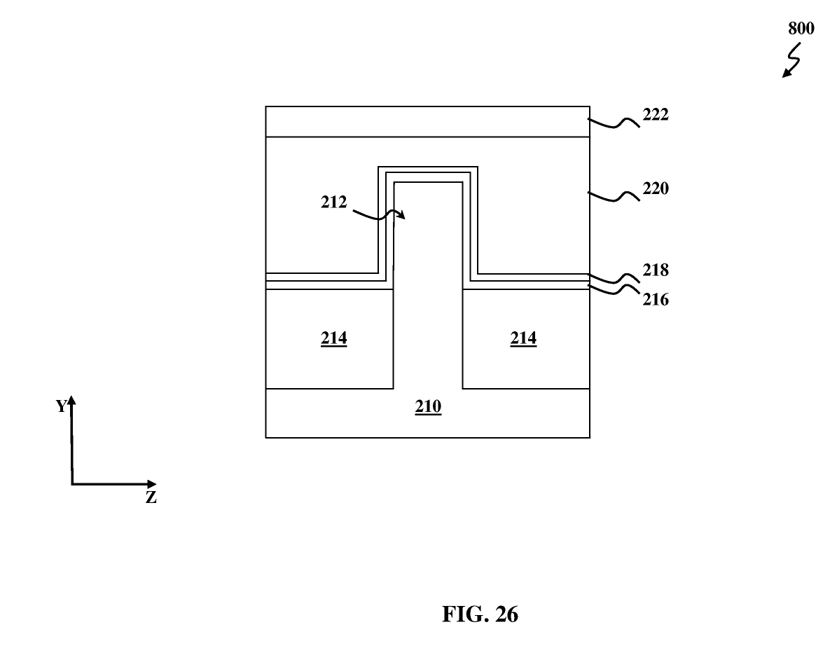

Referring to FIG. 26, after the removal step, a dielectric layer 216 is formed on the FinFET device 800. In the present embodiment, the dielectric layer 216 defined in the FinFET device 800 is substantially similar to the dielectric layer 216 of the FinFET device 200 in terms of composition, formation and configuration. In an alternative embodiment, they are different. A WFMG layer 218 is formed over the dielectric layer 216. In the present embodiment, the WFMG layer 218 defined in the FinFET device 800 is substantially similar to the WFMG layer 218 of the FinFET device 200 in terms of composition, formation and configuration. In an alternative embodiment, they are different. Formed over the WFMG layer 218 is a gate structure 220. In the present embodiment, the gate structure 220 defined in the FinFET device 800 is substantially similar to the gate structure 220 of the FinFET device 200 in terms of composition, formation and configuration. In an alternative embodiment, they are different. Formed over the gate structure 220 is a metal layer 222. In the present embodiment, the metal layer 222 defined in the FinFET device 800 is substantially similar to the metal layer 222 of the FinFET device 200 in terms of composition, formation and configuration. In an alternative embodiment, they are different.

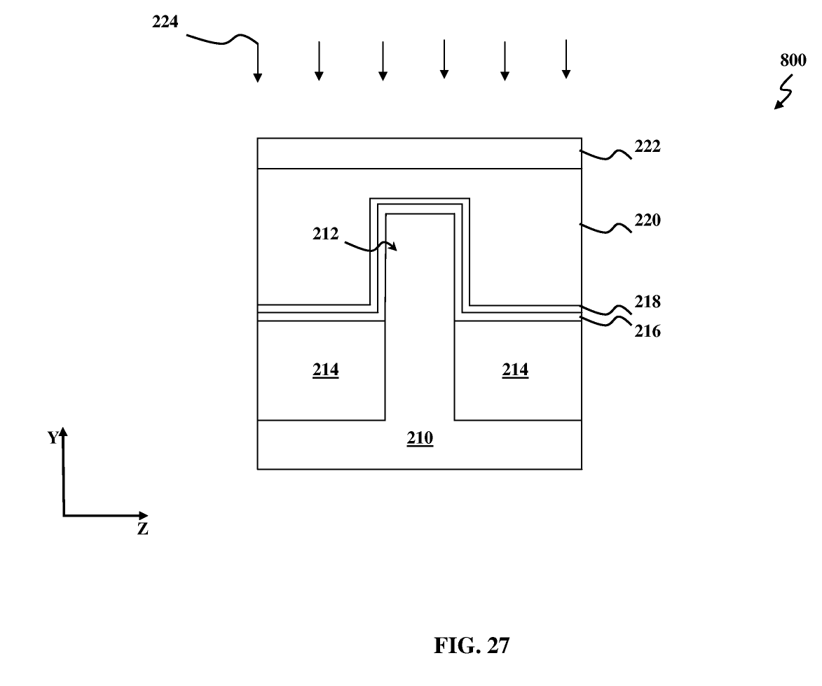

Referring to FIG. 27, a reaction process 224 is performed on the FinFET device 800 to cause a reaction between the Poly-Si of the gate structure 220 and the metal layer 222 such that silicide is formed. In the present embodiment, the reaction process 224 of FIG. 27 is substantially similar to the reaction process 224 of FIG. 5. In an alternative embodiment, they are different.

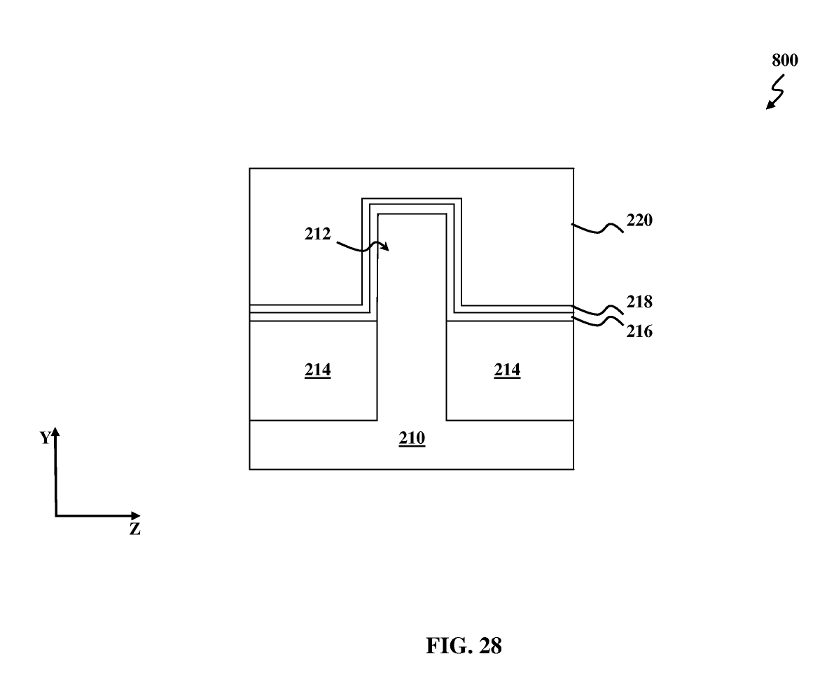

Referring to FIG. 28, after the reaction process 224, portions of the metal layer 222 that have not reacted are removed. For example, in the present embodiment, the non-reacted metal layer 222 is removed by an etching process. The etching process may include a wet etching or dry etching process, or a combination thereof.

The FinFET device 800 of method 700 may be implemented as a PMOS FinFET device or a NMOS FinFET device. Further, the PMOS and NMOS FinFET device 800 can be fabricated in a single integrated circuit device using the method 700. The FinFET device 800 may include additional features, which may be formed by subsequent processing. For example, various contacts/vias/lines and multilayer interconnect features (e.g., metal layers and interlayer dielectrics) may be formed over the substrate 210, configured to connect the various features or structures of the FinFET device 800. The additional features may provide electrical interconnection to the device 800. For example, a multilayer interconnection includes vertical interconnects, such as conventional vias or contacts, and horizontal interconnects, such as metal lines. The various interconnection features may implement various conductive materials including copper, tungsten, and/or silicide. In one example, a damascene and/or dual damascene process is used to form a copper related multilayer interconnection structure.

The FinFET device 800 includes similar strain characteristics as that of FinFET device 200 and 300. Accordingly, the FinFET device 800 benefits from the disclosed embodiment of method 700 by enhancing carrier mobility. Also, FinFET device 800 benefits from the embodiment of method 700 by having a lower thermal history. In addition, as note above, because the gate structure 220 is formed over the WFMG layer 218 rather than directly over the dielectric layer 216, Fermi level pinning effect (i.e., a defect) may be minimized or even eliminated. Further, the method 700 disclosed herein is easily implemented into current processing. It is understood that different embodiments may have different advantages, and no particular advantage is necessarily required of any embodiment.

Thus, provided is a semiconductor device. An exemplary semiconductor device includes a substrate and a 3D structure disposed over the substrate. The semiconductor device further includes a dielectric layer disposed over the 3D structure, a WFMG layer disposed over the dielectric layer, and a gate structure disposed over the WFMG layer. The gate structure traverses the 3D structure and separates a source region and a drain region of the 3D structure. The source and drain region define a channel region therebetween. The gate structure induces a stress in the channel region.

In certain embodiments, the substrate is selected from the group consisting of bulk silicon and silicon-on-insulator (SOI). In various embodiments, the gate structure does not operate as a work function metal. In some embodiments, the semiconductor device is one of a PMOS FinFET device or a NMOS FinFET device and the semiconductor device is included in an integrated circuit device. In further embodiments, the 3D structure includes silicon germanium, the gate structure includes silicide that is metal rich, and the stress in the channel region is a tensile stress in a current flow direction.

Also provided is a method. The method includes providing a substrate and forming a 3D structure over the substrate. The method further includes forming a dielectric layer over a portion of the 3D structure, forming a work function metal group (WFMG) layer over the dielectric layer, and forming a gate structure over the WFMG layer. The gate structure separates a source region and a drain region of the 3D structure. The source and drain region define a channel region therebetween. The method further includes performing a reaction process on the gate structure such that responsive to the reaction process a volume of the gate structure changes.

In some embodiments, the method further comprises after forming the dielectric layer and before forming the WFMG layer, forming a dummy metal layer over the dielectric layer; thereafter, forming a dummy gate structure over the dummy metal layer; thereafter, performing a thermal process on the 3D structure; and thereafter, removing the dummy gate structure and the dummy metal layer. In alternative embodiments, the method further comprises after forming the dielectric layer and after forming the WFMG layer, forming a dummy gate structure over the WFMG layer; performing a thermal process on the 3D structure including the dummy gate structure; and removing the dummy gate structure. In various embodiments, the method further comprises after forming the 3D structure and before forming the dielectric layer, forming a dummy dielectric layer over a portion of the 3D structure; thereafter, forming a dummy gate structure over the dummy dielectric layer; thereafter, performing a thermal process on the 3D structure; and thereafter, removing the dummy gate structure and the dummy dielectric layer. In various embodiments the method further comprises before performing the reaction process, forming a metal layer over the gate structure.

In certain embodiments, the gate structure includes Poly-Si; the reaction process is an annealing process; and the annealing process is performed such that the metal layer is able to react with gate structure including Poly-Si to form silicide, and the gate structure includes the formed silicide, and wherein the formed silicide is metal rich. In some embodiments, the gate structure includes a metal, and the reaction process is an implantation process that implants the gate structure including metal with impurities to form silicide. In various embodiments, the volume of the gate structure changes such that it expands. In further embodiments, the volume of the gate structure changes such that it shrinks. In some embodiments, the change in volume of the gate structure induces one of a compressive stress or a tensile stress in a current flow direction of the channel region.

Also provided is a alternative embodiment of a method for manufacturing a FinFET device. The method includes providing a semiconductor substrate and forming a fin structure over the semiconductor substrate. The method further includes forming a dielectric layer over a portion of the fin structure and forming a work function metal group (WFMG) layer over the dielectric layer. The method also includes forming a gate structure including Poly-Si over the WFMG layer. The gate structure traverses the fin structure. The gate structure separates a source region and a drain region of the fin structure. The source and drain region define a channel region therebetween. The method further includes forming a metal layer over the gate structure and annealing the gate structure including Poly-Si and the metal layer such that the metal layer is able to react with Poly-Si of the gate structure to form silicide; and responsive to the annealing, a volume of the gate structure changes such that a stress is induced in the channel region.

In some embodiments, the method further comprises forming a STI feature in the semiconductor substrate and removing the metal layer that has not reacted with the Poly-Si of the gate structure in the annealing. In various embodiments, the method further comprises after forming the fin structure and before forming the dielectric layer, forming a dummy dielectric layer over a portion of the fin structure; thereafter, forming a dummy gate structure over the dummy dielectric layer such that the dummy gate structure traverses the fin structure; thereafter, performing a thermal process on the FinFET device; and thereafter, removing the dummy gate structure and the dummy dielectric layer. In further embodiments, the method further comprises after forming the dielectric layer and before forming the WFMG layer, forming a dummy metal layer over the dielectric layer; thereafter, forming a dummy gate structure over the dummy metal layer, such that the dummy gate structure traverses the fin structure; thereafter, performing a thermal process on the FinFET device; and thereafter, removing the dummy gate structure and the dummy metal layer.

The above disclosure provides many different embodiments, or examples, for implementing different features of the invention. Specific examples of components and arrangements are described above to simplify the present disclosure. These are, of course, merely examples and are not intended to be limiting. Accordingly, the components disclosed herein may be arranged, combined, or configured in ways different from the exemplary embodiments shown herein without departing from the scope of the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a 3D structure disposed over the substrate;
a dielectric layer disposed over the 3D structure;
a work function metal group (WFMG) layer disposed over the dielectric layer; and
a gate structure disposed over the WFMG layer,
wherein the gate structure traverses the 3D structure and separates a source region and a drain region of the 3D structure, the source and drain region defining a channel region therebetween, and
wherein the gate structure induces a stress in the channel region.

2. The semiconductor device of claim 1 wherein the substrate is selected from the group consisting of bulk silicon and silicon-on-insulator (SOI).

3. The semiconductor device of claim 1 wherein the gate structure does not operate as a work function metal.

4. The semiconductor device of claim 1 wherein the semiconductor device is one of a PMOS FinFET device or a NMOS FinFET device, and wherein the semiconductor device is included in an integrated circuit device.

5. The semiconductor device of claim 1 the stress in the channel region is a compressive stress in a current flow direction.

6. The semiconductor device of claim 1 wherein the 3D structure includes silicon germanium and the gate structure includes silicide that is metal rich, and wherein the stress in the channel region is a tensile stress in a current flow direction.

7. A method of manufacturing, comprising:
providing a substrate;
forming a 3D structure over the substrate;
forming a dielectric layer over a portion of the 3D structure;
forming a work function metal group (WFMG) layer over the dielectric layer;
forming a gate structure over the WFMG layer, the gate structure separating a source region and a drain region of the 3D structure, wherein the source and drain region define a channel region therebetween; and
performing a reaction process on the gate structure, wherein responsive to the reaction process a volume of the gate structure changes.

8. The method of claim 7 further comprising:
after forming the dielectric layer and after forming the WFMG layer, forming a dummy gate structure over the WFMG layer;
performing a thermal process on the 3D structure including the dummy gate structure; and
removing the dummy gate structure.

9. The method of claim 7 further comprising:
after forming the dielectric layer and before forming the WFMG layer, forming a dummy metal layer over the dielectric layer;
forming a dummy gate structure over the dummy metal layer;
performing a thermal process on the 3D structure including the dummy gate structure; and
removing the dummy gate structure and the dummy metal layer.

10. The method of claim 7 further comprising:
after forming the 3D structure and before forming the dielectric layer, forming a dummy dielectric layer over a portion of the 3D structure;
forming a dummy gate structure over the dummy dielectric layer;
performing a thermal process on the 3D structure including the dummy gate structure; and
removing the dummy gate structure and the dummy dielectric layer.

11. The method of claim 7 further comprising:
before performing the reaction process, forming a metal layer over the gate structure

12. The method of claim 11 wherein the gate structure includes Poly-Si, and wherein the reaction process is an annealing process, and wherein the annealing process is performed such that the metal layer is able to react with gate structure including Poly-Si to form silicide.

13. The method of claim 7 wherein the gate structure includes a metal, and wherein the reaction process is an implantation process that implants the gate structure including metal with impurities to form silicide.

14. The method of claim 7 wherein the volume of the gate structure changes such that it expands.

15. The method of claim 7 wherein the volume of the gate structure changes such that it shrinks.

16. The method of claim 7 wherein the change in volume of the gate structure induces one of a compressive stress or a tensile stress in a current flow direction of the channel region.

17. A method of manufacturing a FinFET device comprising:
providing a semiconductor substrate;
forming a fin structure over the semiconductor substrate;
forming a dielectric layer over a portion of the fin structure;
forming a work function metal group (WFMG) layer over the dielectric layer;
forming a gate structure including Poly-Si over the WFMG layer, wherein the gate structure traverses the fin structure, and wherein the gate structure separates a source region and a drain region of the fin structure, the source and drain region defining a channel region therebetween;
forming a metal layer over the gate structure;
annealing the gate structure including Poly-Si and the metal layer such that the metal layer is able to react with Poly-Si of the gate structure to form silicide; and
responsive to the annealing a volume of the gate structure changes such that a stress is induced in the channel region.

18. The method of claim 17 further comprising:
forming a STI feature in the semiconductor substrate; and
removing the metal layer that has not reacted with the Poly-Si of the gate structure in the annealing.

19. The method of claim 17 further comprising:
after forming the fin structure and before forming the dielectric layer, forming a dummy dielectric layer over a portion of the fin structure;
forming a dummy gate structure over the dummy dielectric layer, wherein the dummy gate structure traverses the fin structure;
performing a thermal process on the FinFET device including the dummy gate structure; and
removing the dummy gate structure and the dummy dielectric layer.

20. A method of claim 17 further comprising:
after forming the dielectric layer and before forming the WFMG layer, forming a dummy metal layer over the dielectric layer;
forming a dummy gate structure over the dummy metal layer, wherein the dummy gate structure traverses the fin structure;
performing a thermal process on the FinFET device including the dummy gate structure; and
removing the dummy gate structure and the dummy metal layer.
